(19) United States
(12) Patent Application Publication
(10) Pub. No.: US 2015/0221501 A1
(43) Pub. Date: Aug. 6, 2015

(54) IMPRINT METHOD, TEMPLATE, AND IMPRINT APPARATUS

(71) Applicant: KABUSHIKI KAISHA TOSHIBA, Tokyo (JP)

(72) Inventors: Masatoshi Tsuji, Kawasaki-shi (JP); Masayuki Hatano, Yokohama-shi (JP)

(73) Assignee: KABUSHIKI KAISHA TOSHIBA, Tokyo (JP)

(21) Appl. No.: 14/254,191

(22) Filed: Apr. 16, 2014

(30) Foreign Application Priority Data
Jan. 31, 2014 (JP) 2014-016945

(51) Int. Cl. H01L 21/027

(52) U.S. Cl. CPC H01L 21/0273; H01L 21/027

(57) ABSTRACT

According to one embodiment, in an imprint method, a template in which a pattern is arranged in a central region and an outside region is contacted against a first imprint shot. Light is irradiated via a dimming member so that a partial region of a resist contacted by the outside region has hardness lower than target hardness, and thereafter, the template is separated. Furthermore, the template is contacted against a second imprint shot so that the first and second imprint shots are superposed in the partial region. Light is then irradiated so that the resist in the partial region reaches the target hardness, and thereafter, the template is separated.

### CROSS-REFERENCE TO RELATED APPLICATIONS

This application is based upon and claims the benefit of priority from Japanese Patent Application No. 2014-016945, filed on Jan. 31, 2014; the entire contents of which are incorporated herein by reference.

### FIELD

Embodiments described herein relate to an imprint method, a template, and an imprint apparatus.

### BACKGROUND

An imprint technique has been known as one technique of downsizing an element pattern constituting a semiconductor device. In the imprint technique, a template having a pattern with a pattern size to be transferred has been employed. At the time of performing imprint, a resist pattern is formed on a substrate by curing a resist in a state with a template imprinted to the resist on the substrate.

In the imprint technique, by using a template having a fine template pattern, a fine pattern can be formed without using any complicated optical system and a multi-patterning technique that repeats pattern formation and processing for plural times. Accordingly, the imprint technique has been regarded as the most effective low-cost lithographic process in a semiconductor device.

In a conventional optical exposure apparatus, a part of adjacent shots are superposed to perform patterning in order to correct misalignment between the adjacent shots. On the other hand, in an existing imprint technique, it is difficult to superpose adjacent shots to perform imprint. This is because the resist cures in a region where light is irradiated. If a template is superposed and imprinted on the cured resist, breakage of the template may occur.

Therefore, in the imprint, it is desired to correct misalignment between the adjacent shots without damaging the template.

### BRIEF DESCRIPTION OF THE DRAWINGS

FIG. 1 illustrates a configuration of an imprint apparatus according to a first embodiment;

FIG. 2 illustrates a sectional configuration of a template provided with a dimming member;

FIG. 3 is an explanatory diagram of a shape of kerf region;

FIG. 4 is an explanatory diagram of a superposed region between adjacent shots;

FIG. 5 is an a-a cross section of a wafer shown in FIG. 4;

FIG. 6 is an explanatory diagram of a shape of a kerf region of a template according to a second embodiment;

FIG. 7 illustrates a configuration of a template according to a third embodiment;

FIG. 8 is an explanatory diagram of an arrangement of imprint shots; and

FIG. 9 illustrates a configuration of an imprint apparatus according to a fourth embodiment.

### DETAILED DESCRIPTION

According to one embodiment, an imprint method is provided. In the imprint method, a first contacting step, a first irradiation step, a first separating step, a second contacting step, a second irradiation step, and a second separating step are performed. At the first contacting step, a template having a first pattern arranged in a central region and a second pattern arranged in a first outside region which is a region outside of the central region, is contacted against a first imprint shot in a resist on a substrate. At the first irradiation step, when light for curing the resist is irradiated to the first imprint shot via the template, the light is irradiated to the resist in a partial region of a first resist region contacted by the first outside region, via a dimming member that dims the amount of light so that the resist has hardness lower than target hardness. At the first separating step, the template is separated from the first imprint shot. At the second contacting step, the template is contacted against a second imprint shot so that the second imprint shot adjacent to the first imprint shot and the first imprint shot are superposed in a superposed region including the partial region. At the second irradiation step, when the light is irradiated to the second imprint shot via the template, the light is irradiated so that the resist in the partial region reaches the target hardness. At the second separating step, the template is separated from the second imprint shot,

Exemplary embodiments of an imprint method, template and an imprint apparatus will be explained, below in detail with reference to the accompanying drawings. The present invention is not limited, to the following embodiments.

### First Embodiment

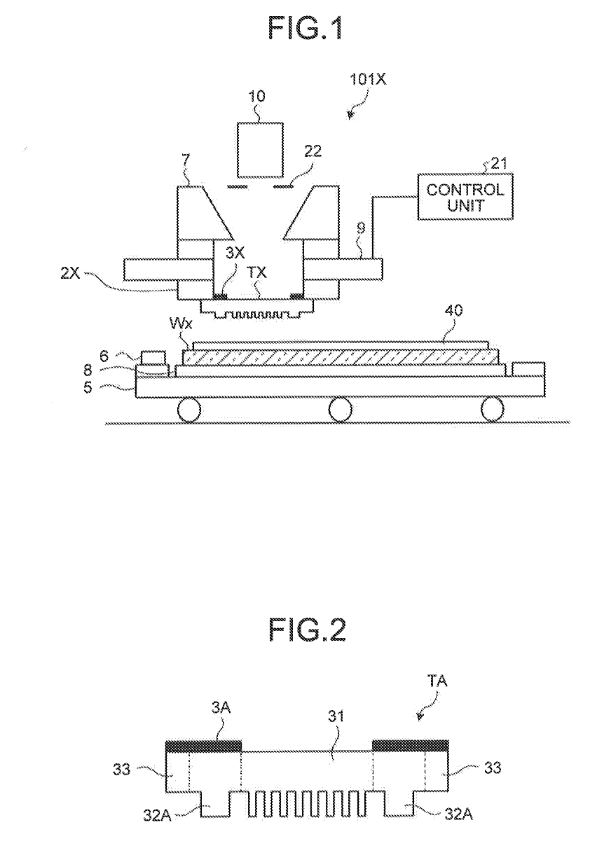

FIG. 1 illustrates a configuration of an imprint apparatus according to a first embodiment. An imprint apparatus 101X transfers a template pattern. (a circuit pattern or the like) of a template (an original plate) TX serving as a rod substrate to a substrate to be transferred. (a substrate to be processed) rather a wafer Wx. The imprint apparatus 101X according to the first embodiment arranges a dimming member 3X on a kerf region (a rectangular annular region.) of the template TX to superpose and imprint a part of adjacent shots.

The imprint apparatus 101X includes an original plate stage X, a substrate chuck 8, a sample stage 5, a reference mark 6, an alignment sensor 7, a stage base 9, a UV light source 10, and a shutter 22. The imprint apparatus 11X according to the first embodiment also includes a control unit 21.

The sample stage 5 is mounted with the wafer Wx, and moves on a plane (on a horizontal plane) parallel to the wafer Wx mounted thereon. The sample stage 5 carries in the wafer Wx applied with a resist 40 as a transfer material on the whole surface or substantially the whole surface thereof (the WOOS surface except for an edge), and moves the wafer ha to below the template TX. At the time of performing an imprint process with respect to the wafer Wx, the sample stage 5 moves respective shot positions on the wafer Wx to below the template TX sequentially.

The substrate chuck 8 is provided on the sample stage 5. The substrate chuck 8 fixes the wafer ha at a predetermined position on the sample stage 5. The reference mark 6 is provided on the sample stage 5. The reference mark 6 is for detecting the position of the sample stage 5, and is used for position alignment at the time of loading the wafer Wx onto the sample stage 5.

The original plate stage 2X is provided on a bottom surface side (on the side of the wafer Wx) of the stage base 9. The original plate stage 2X fixes the template TX to a predetermined position from a rear surface side (a surface on which a template pattern is not formed) of the template TX by vacuum suction or the like.

The stage base 9 supports the template TX by the original plate stage 2X, and also contacts the template pattern of the template TX against the resist 40 on the wafer Wx. The stage base 9 moves in an up-and-down direction (a vertical direction) to contact the template TX against the resist, and separate the template TX from the resist 40. The resist 40 to be used for imprint is a resin material (a photo-curing agent) having a characteristic such as photo-curing property. The alignment sensor 7 is provided on the stage base 9. The alignment sensor detects the position of the wafer Wx and the position of the template TX.

The UV light source 10 irradiates light such as UV light and is provided above the stage base 9. The UV light source 10 UV light from above the template TX, while the template TX is contacted against the resist 40.

The shutter (irradiation unit) 22 changes over whether to allow or block passage of UV light irradiated from the UV light source 10. In a state opened by the control unit 21, the shutter 22 allows passage of UV light irradiated from the UV light source 10 toward the template TX, and in a state closed by the control unit 21, the shutter 22 blocks passage of UV light irradiated from the UV light source 10. It can be changed over whether to allow or block passage of UV light by a mechanism other than a shutter.

The dimming member 3X can be constituted, for example, by using chromium or by using low purity quartz. The dimming member 3X is arranged in an optical path between the UV light source 10 and the resist 40. The UV light source 10 according to the first embodiment irradiates UV light from above the dimming member 3X arranged on a kerf region, which is an outer peripheral region of the template TX, to cure the resist 40 at a position contacted against the template TX. The UV light reaches the resist 40 via the template TX at a position (a body pattern region) on the template TX where the dimming member 3X is not arranged. A part of the UV light is dimmed by the dimming member 3X and reaches the resist 40 via the template TX at a position on the template TX where the dimming member 3X is arranged.

Because the dimming member 3X is arranged on the kerf region of the template TX, the UV light dimmed by the dimming member 3X is irradiated to the kerf region of the resist 40. For example, the dimming member 3X allows passage of UV light only by an amount enough for the resist 40 to be cured to hardness half the desired hardness (target hardness) by one imprint process.

Accordingly, the UV light dimmed by the dimming member 3X causes the resist 40 to promote the degree of cure by half the desired hardness bi one irradiation. Meanwhile, the UV light irradiated via the body pattern region where the dimming member 3X is not arranged cures the resist 40 to the desired hardness. The dimming member 3X can be formed on an upper surface of the template TX or can be formed on the original plate stage 2X.

The control unit 21 is connected to respective constituent elements of the imprint apparatus 101X to control the respective constituent elements. FIG. 1 illustrates a state where the control unit 21 is connected to the stage base 9, and illustrations of connection with other constituent elements are omitted. The control unit 21 according to the first embodiment imprints the template TX on the resist 40 so that the kerf regions of adjacent shots are superposed on or other.

At the time of performing imprint on the wafer Wx, the wafer Wx applied with the resist 40 on substantially the whole surface is moved to immediately below the template TX. The template TX is then contacted against the resist 40 on the wafer Wx.

After the template TX and the resist 40 are brought into contact with each other for a predetermined time, the control unit 21 causes the UV light source 10 to irradiate UV light to the resist 40 in this state to cure the resist 40. Accordingly, a transfer pattern corresponding to the template pattern in the body pattern region is patterned on the resist 40 on the wafer Wx. The resist 40 in the kerf region becomes a semi-cured state.

After the template TX is separated from the resist 40, the shape of the resist 40 does not deform until the template TX is imprinted next, and the resist 40 can be in a cured state other than the semi-cured state so long as the resist 40 does not damage the template TX even when the resist 40 comes in contact with the template pattern at the time of subsequent imprint processes. For example, the imprint process is performed so that the cured state of the kerf region does not proceed more than the cured state of the body pattern region (so that the hardness is lower than the target hardness). In other words, the imprint process is performed so that an irradiation amount of UV light per unit area is less in the kerf region than in the body pattern region.

After the imprint process to a first shot is performed, the imprint process to a second shot adjacent to the first shot is performed. At this time, the imprint process to the second shot is performed so that the kerf region in the first shot and the kerf region in the second shot are superposed on each other. In this manner, in the first embodiment, the imprint process to each shot is performed so that the kerf regions are superposed on each other in the adjacent shots. The imprint apparatus 101X repeats this imprint process for each shot.

A configuration of the dimming member 3X is explained next. A case where a dimming member 3A as an example of the dimming member 3X is formed on a template TA as an example of the template TX is explained. An imprint process using an imprint apparatus 101A (not shown) as an example of the imprint apparatus 101X and the template TA is explained below. When the imprint process is performed by using the template TA provided with the dimming member 3A, the dimming member 3X does not need to be arranged in the imprint apparatus 101X.

FIG. 2 illustrates a sectional configuration of a template provided with a dimming member. The template TA is formed by using a plate-like member, and includes the dimming member 3A on a surface (an upper surface) opposite to a surface where a template pattern is formed (a bottom surface).

The template TA includes a body pattern region 31 in which a circuit pattern and the like are arranged, a kerf region 32A in which various marks and the like are arranged, and an outer peripheral region 33 in which a template pattern is not arranged. For example, an alignment mark and an O/L (overlay) mark are arranged in the kart region 32A.

The dimming member 3A is arranged above the kerf region 32A and the outer peripheral region 33. According to this configuration, UV light is irradiated to the test region 32A and the outer peripheral region 33, which are parts on the bottom side of the dimming member 3A, in an amount less than the amount irradiated to the body pattern region 31. In the first embodiment, the dimming member 3A covers not a part of the kerf region 32A but the whole surface of the kerf region 32A.

Because the dimming member 3A is arranged on the outer peripheral region 33 in the template TA, it can be prevented that the UV light leaking from the body pattern region 31 and the kerf region 32A is irradiated to an adjacent imprint shot. A member (a light shielding member or the like) having a larger dimming amount than the dimming member 3A can be arranged in the outer peripheral region 33 instead of the dimming member 3A.

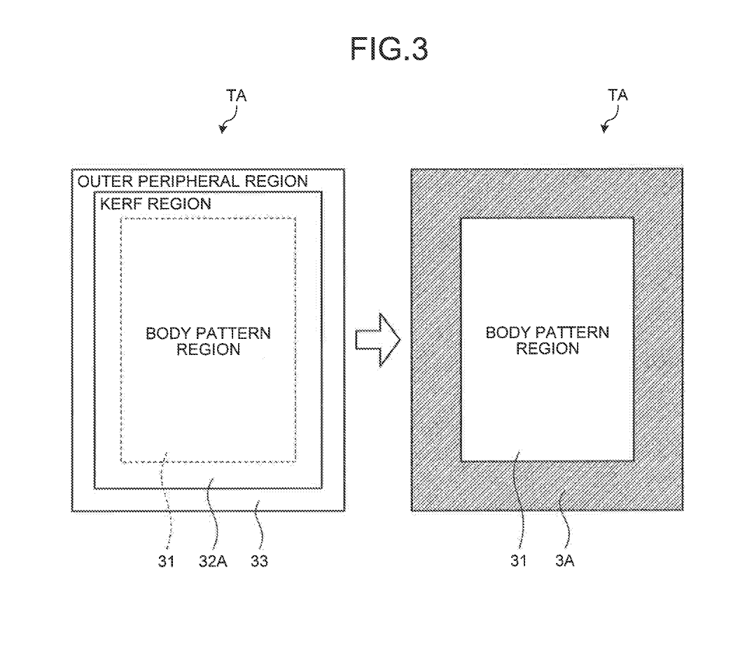

FIG. 3 is an explanatory diagram of a shape of the kerf region. FIG. 3 illustrates a configuration of an upper surface of the template. The template TA in which the dimming member 3A is not shown is shown on the left side in FIG. 3, and the temple TA after the dimming member 3A is arranged is shown on the right side in FIG. 3.

When the template TA is viewed from the upper surface side, the body pattern region 31 (a central region) has, for example, a rectangular region and is arranged in a central part of the template TA. When the template TA is viewed from the upper surface side, the kerf region 32A has, for example, a rectangular annular region and is arranged outside of the body pattern region 31. When, the template TA is viewed from the upper surface side, the outer peripheral region 33 has, for example, a rectangular annular region and is arranged outside of the kerf region 32A.

The kerf region 32A includes four apex regions serving as an apex of the rectangular annular region, and four side regions serving as sides of the rectangular annular region. In the side region of the kerf region 32A, imprint (superposition) is performed twice between the adjacent shots. In the apex region of the kerf region 32A, imprint (superposition) is performed four times between the adjacent shots.

For example, in the side region arranged on the right side of the body pattern region 31, superposition is performed with the right shot. In the apex region arranged on the upper right side of the body pattern region 31, superposition is performed between the right shot, the upper shot, and the upper right shot.

In the first embodiment, the dimming member 3A is arranged on the upper surfaces of the kerf region 32A and the outer peripheral region 33. Because superposition is performed four times in the apex region of the kerf region 32A, UV light irradiation is performed four times in total. Therefore, at the time of performing third and fourth imprint process, superposition is performed with respect to the apex region which has cured already. In the first embodiment, no mark or the like is arranged in the apex region where superposition is performed four times, and the mark or the like is arranged in the side region.

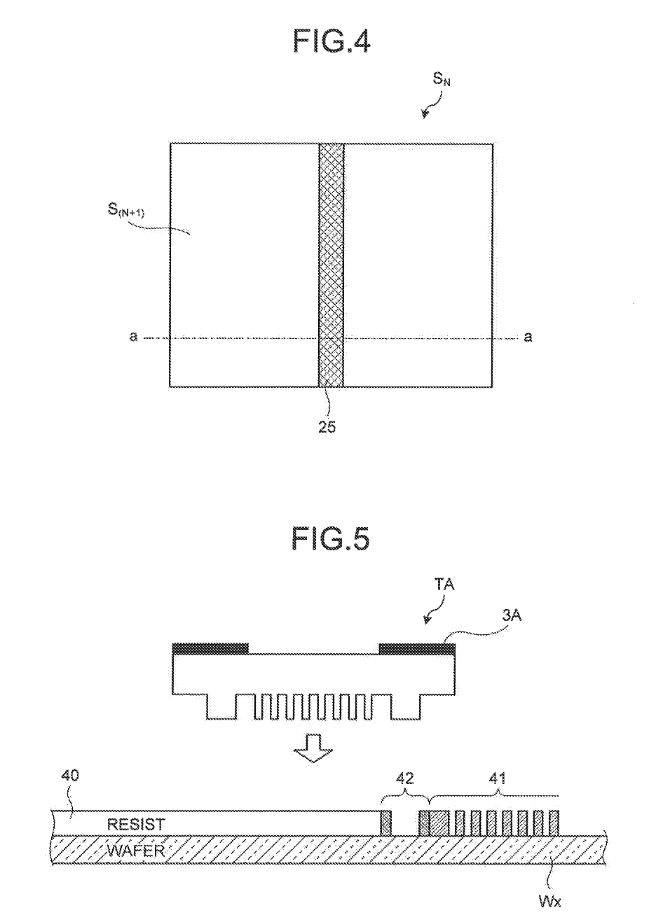

FIG. 4 is an explanatory diagram of a superposed region between the adjacent shots. FIG. 4 illustrates an imprint shpt when the wafer Wx is viewed from an upper surface side. After performing an imprint process to an Nth shot S_{N} (N is a natural number), the imprint apparatus 101A performs an imprint process to an (N+1)th shot S_{(N+1)}. In this case, a part of the kerf region 32A is contacted against a region 25 between the imprint shots S_{N} and S_{N} both in the imprint process to the imprint shot S_{N} and in the imprint process to the imprint shot S_{(N+1).}

FIG. 5 is an a-a cross section of the wafer shown in FIG. 4. When the imprint process is performed to the Nth shot S_{N}, a template pattern (a circuit pattern 41) is formed in a region on the resist 40 corresponding to the body pattern region 31 of the template TA. The circuit body pattern 41 is in a completely cured state by irradiation of the UV light.

Meanwhile, a kerf pattern 42 is formed in a region on the resist 40 corresponding to the kerf region 32A of the template TA. The kerf pattern 42 is in a semi-cured state because the UV light is irradiated thereto via the dimming member 3A.

Subsequently, at the time of performing the imprint process to the (N+1)th shot S(_{N+1}), the kerf region 32A of the template TA is imprinted to the kerf pattern 42 in the semi-cured state. In other words, the kerf region 32A is imprinted twice to the region between the Nth shot S_{N} and (N+1)th shot S_{(N+1)}.

When the imprint process is performed to the (N+1)th shot the kerf pattern 42 in the semi-cured state because the UV light is irradiated via the dimming member 3A becomes a completely cured state. The kerf pattern 42 in the completely cured state has the same hardness as that of the circuit pattern 41.

In the first embodiment, because UV light is irradiated via the dimming member 3A, the region irradiated with UV light on the resist 40 becomes smaller than the pattern region of the template TA. Therefore, a region in which the resist 40 is completely cured to a desired hardness (the circuit pattern 41) and a semi-cured region (the kerf pattern 42) are formed in one shot. Accordingly, in the half red region of the resist 40, the adjacent shots can be superposed and imprinted on each other. At the time of performing imprint to the adjacent shots the region to be superposed and imprinted (an uncured portion of a previous shot) is completely cured to a desired hardness.

At the time of overstriking the template TA between the adjacent shots, the hardness of the resist 40 is different between a semi-cured portion of the previous shot and the next shot. Therefore, the imprint apparatus 101A can change the pressure at the time of imprinting the template TA for each region of the template TA.

In this case, for example, the imprint apparatus 101A imprints a region (the kerf region 32A) of the template TA to be contacted against the semi-cured portion of the resist 40 with a pressure stronger than the region (the body pattern region 31) to be contacted against the uncured portion of the resist 40. Accordingly, flexure of the template TA due to the hardness of each region of the resist 40 is corrected.

The thickness of the template TA can be changed in each region of the template TA. In this case, for example, the region of the template TA to be contacted against the semi-cured portion of the resist 40 is formed thicker than the region to be contacted against the uncured portion of the resist 40. In this case, the thickness of the template TA in each region is adjusted to have stiffness corresponding to the hardness of the resist 40 to be contacted. A method of changing the thickness of the template TA in each region includes, for example, ion implantation and etching.

The depth of the template pattern of the template TA can be changed in each region of the template TA. In this case, for example a groove of the template TA in the template pattern to be contacted against the semi-cured portion of the resist 40 is formed deeper than a groove in the template pattern to be contacted against the uncured portion of the resist 40. In this case, the depth of the template pattern is adjusted to have a depth corresponding to the hardness of the resist 40 to be contacted. A method of changing the depth of the template pattern in each region includes, for example, etching.

An application unit of the resist 40 can be provided in the imprint apparatus 101A. The application unit applies the resist 40 to the whole surface of the we Wx. In that case, the imprint apparatus 101A performs an imprint process to the wafer Wx applied with the resist 40 by the application unit.

Furthermore, an ink-let liquid-dropping device can drop the resist 40 onto the wafer Wx. In this case, the imprint apparatus 101A can repeat dropping of the resist 40 and the imprint process to the resist 40 for every one shot.

UV light irradiated to the body pattern region 31 may leak to the vicinity of the kerf region of the resist 40 to which the body pattern region 31 is imprinted. Therefore, a dimming member haying a larger dimming rate than the dimming member 3A can be arranged in the region near the body pattern region 31 of the dimming member 3A.

In the region against which the outer peripheral region 33 is contacted, the resist 40 does not need to be semi-cured. Accordingly, in the region of the dimming member 3A near the outer peripheral region 33, a dimming member having a larger diming rate than the dimming member 3A (a complete light-shielding member or the like) can be arranged.

In this manner, in the first embodiment, a mark or the like is arranged in the kerf region 32A of the template TA. The imprint apparatus 101A irradiates UV light via the dimming member 3A to the region of the resist 40 imprinted with the kerf region 32A, thereby semi-curing the resist 40. The imprint apparatus 101A also superposes and imprints the region imprinted with the tart region 32A between the adjacent shots.

Consequently, even when a mark or the like is arranged between the adjacent shots, the adjacent shots can be superpose and imprinted without damaging the template TA. Further, misalignment between the adjacent shots can be corrected, and the template pattern can be imprinted to the resist 40 efficiently.

### Second Embodiment

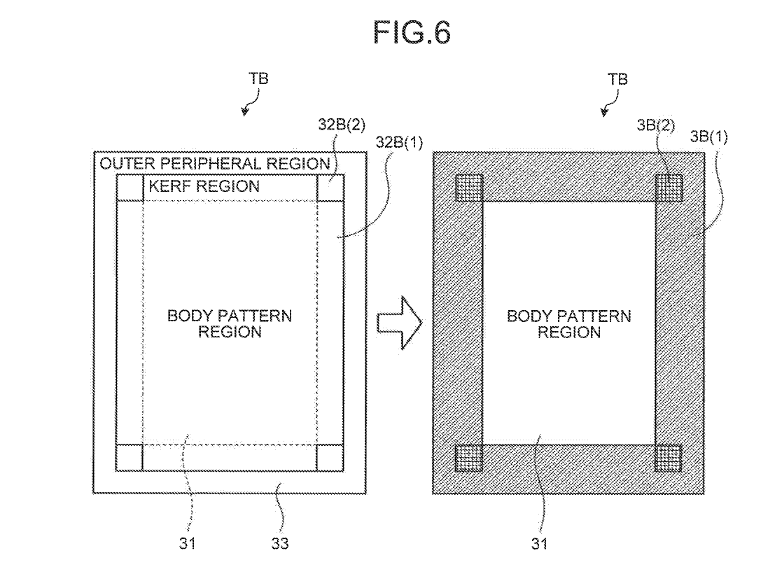

A second embodiment is explained next with reference to FIG. 6. In the second embodiment, UV light 2 is irradiated to a region where four shots are superposed on each other via a member having a larger light shielding degree than the dimming member 3A.

FIG. 6 is an explanatory diagram of a shape of a kerf region of a template according to the second embodiment. In FIG. 6, a case where dimming members 3B(1) and 3B(2) as an example of the dimming member 3X are formed template TB as an example of the template TX is explained. The constituent elements exhibiting identical functions as the template TA according to the first embodiment shown in FIG. 3 among the constituent elements shown in FIG. 6 are designated by like reference signs and redundant explanations will be omitted.

A configuration of an upper surface of the template TB in which illustration of the dimming members 3B(1) and 3B(2) are omitted is shown on the left side of FIG. 6, and the template TB in which the dimming members 3B(1) and 3B(2) are arranged is shown on the right side of FIG. 6. A case where the template includes kerf regions 32B(1) and 32B(2) is explained. A region including the kerf regions 32B(1) and 32)3(2) corresponds to the kerf region 32A, where a mart or the like is arranged.

The kerf region 32B(2) is an apex region serving as an apex of a rectangular annular region of the kerf region 32A, and the kerf region 32B(1) is a side region serving as a side of the rectangular annular region of the kerf region 32A. The kerf region. 32B(1) is a region where imprint (superposition) is performed twice between adjacent shots. Further, the kerf region 32B(2) is a region where imprint (superposition) is performed tour times between the adjacent shots.

For example, in a region arranged on the right side of the body pattern region 31 of the kerf regions 32B(1), superposition is performed with the right shot. In a region arranged on the upper right of the body pattern region 31 of the kerf regions 32B(2), superposition is performed with the right shot, the upper shot, and the upper right shot.

According to the second embodiment, a dimming member 3B(1) is arranged on upper surfaces of the kerf regions 32B(1) and the outer peripheral region 33 with respect to the template TB. Further, a dimming member 3B(2) is arranged on upper surfaces of the kerf regions 32B(2) with respect to the template TB.

The dimming member 3B(2) has a higher light shielding degree than the dimming member 3B(1). For example, the dimming member 3B(2) transmits UV light by an amount for the resist 40 to be cured up to one fourth the desired hardness by one imprint process. Therefore, the UV light dimmed by the dimming member 3B(2) promotes the degree of cure by one fourth with respect to the resist 40 by one irradiation.

The dimming member 3B(1) has the same property as the dimming member 3A. Therefore, the dinning member 3B(1) transmits UV light by an amount for the resist 40 to be cured on to half the desired hardness by one imprint process.

The region of the resist 40 where the dimming member 3B(2) is imprinted region where the adjacent templates TB for four shots are imprinted. According to the second embodiment, because UV light dimmed by the dimming member 3B(2) promotes the degree of cure by one fourth with respect to the resist 40, when the imprint process is performed four times with respect to the apex region where four shots are superposed, the resist 40 is completely cured on to the desired hardness.

The resist 40 is not completely cured up to the desired hardness in the first to the third processes of the four imprint processes. Therefore, even when a mark or the like is arranged in the apex region where the dimming member 3B(2) is arranged, the template TB can be prevented from being damaged at the time of performing the imprint process.

The dimming member 3B(2) may not be arranged in the kerf regions 32B(2). Also in this case, the template pattern such as a mark is not arranged in the kerf regions 32B(2).

In this manner, in the second embodiment, the dimming member 3B(2) that promotes the degree of cure by one fourth with respect to the resist 40 is arranged above the hart regions 32B(2) where imprint (superposition) is performed with respect to the template TB four times between the adjacent shots.

Accordingly, even when a mark or the like is arranged in a region where four shots are superposed, the four adjacent shots cart be superposed and imprinted without damaging the template. Further, misalignment between the adjacent shots can be corrected, and the template pattern can be imprinted to the resist 40 efficiently.

### Third Embodiment

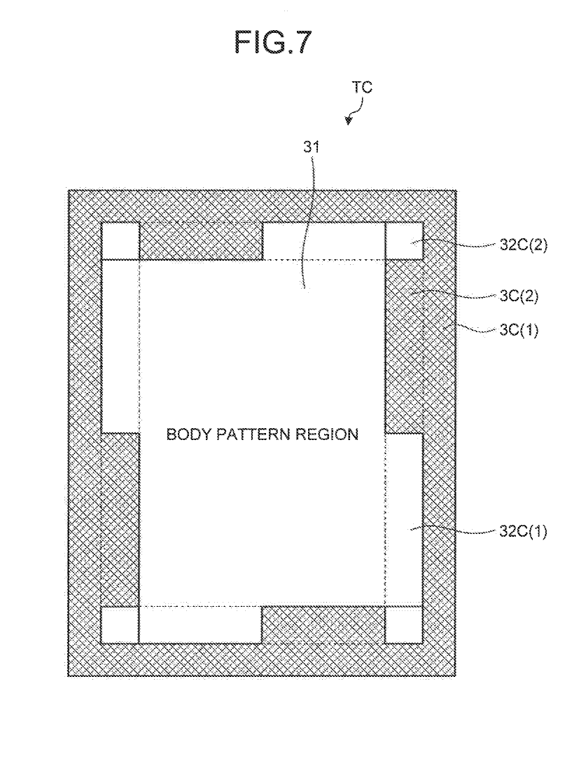

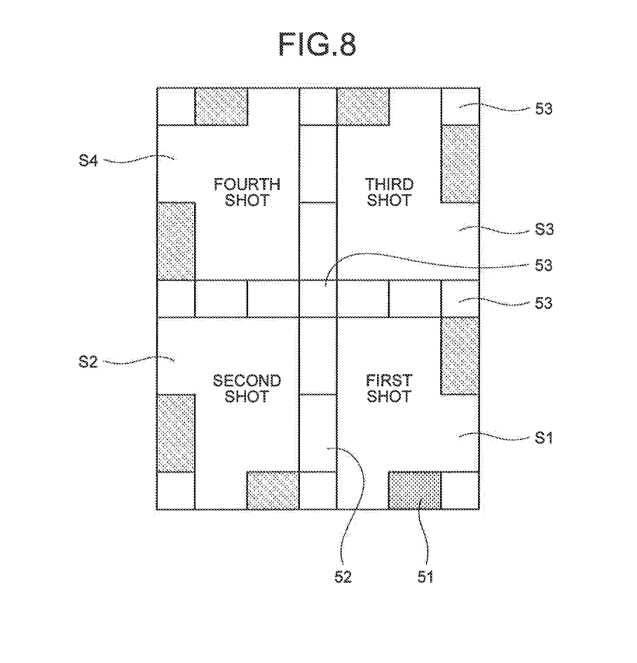

A third embodiment is explained next with reference to FIGS. 7 and 8. According to the third embodiment, a light shielding member is arranged on a kerf region provided in a template, and the light shielding member has a jigsaw shape. In this case, a light shielding member having a shape in which the kerf regions can be superposed between adjacent shots is arranged on the template.

FIG. 7 illustrates a configuration of the template according to the third embodiment. FIG. 7 illustrates a configuration of an upper surface of a template TC. The template TC has the body pattern region 31, the kerf region 32 (not shown in FIG. 7), and the outer peripheral region 33 (not shown in FIG. 7).

In FIG. 7, a case where light shielding members 3C(1) and 3C(2) are arranged on the template TC is shown. Kerf regions 32C(1) and 32C(2), which are a part of the kerf region 32, are shown and other regions are not shown in FIG. 7.

While the dimming member 3A is arranged on the template TA, the light shielding members 3C(1) and 3C(2) are arranged on the template TC. The kerf regions 32C(1) and 32C(2) of the kerf region 22 are regions where the light shielding member 3C(2) is not arranged, and the light shielding member 3C(2) is arranged in regions other than the kerf regions 32C(1) and 32C(2). In the template TC, the light shielding member 3C(1) is arranged above the outer peripheral region 33. Further, the region where the kerf region 32C(2) is arranged is the same region (the shape and position) as the region where the dimming member 3B(2) is arranged.

A mark or the like is arranged, as in the kerf region 32A, in the region of the Bert region 32C where the kerf region 32C(1) and the light shielding member 3C(2) are arranged. A mark or the like is not arranged in the region of the kerf region 32 where the kerf region 32C(2) is arranged. The light shielding members 3C(1) and 3C(2) slightly transmit UV light to be irradiated.

The light shielding degree of the light shielding members 3C(1) and 3C(2) is such that, for example, when the template TC is separated from the resist 40, the resist 40 is cured to such a degree that the resist 40 is not peeled off from the wafer Wx by the template TC. Further, the light shielding degree of the light shielding members 3C(1) and 3C(2) is such that, for example, the resist 40 is cured to such a degree that the template TC is not damaged by the cured resist 40 when the template TC is contacted against the cured resist 40. The light shielding member 3C(1) according to the third embodiment is arranged in a jigsaw shape in an outer peripheral portion of the body pattern region 31. In other words, the template TC has a jigsaw-shaped open region.

In this manner, the light shielding member 3C(1) is arranged in a shape of jigsaw puzzle pieces (a jigsaw shape). Therefore, the template TC is provided with a region where the light shielding member 3C(2) is arranged (a concave open region) and a region where the light shielding member 3C(2) is not arranged (a convex open region). The convex region is the kerf region 32C(1) that protrudes from the body pattern region 31 in the central portion when the imprint shot is viewed from an upper surface. Further, the concave region is a portion of the kerf region 32 where the Kerf region 32C(1) is not arranged, when the imprint shot is viewed from an upper surface. In the template TC, the convex region and the concave region are arranged so that when the convex region and the concave region are fitted to each other between the adjacent shots, the convex regions are not superposed on each other and the concave regions are not superposed on each other.

Specifically, in the template TC, the convex region and the concave region are arranged so that the convex region and the concave region face each other, putting the body pattern region 31 therebetween. In other words, the template TC is formed so that the kerf region 32C(1) and regions other than the kerf region 32C(1) of the kerf region 32 are fitted to each other between adjacent shots to form a rectangular region (a scribe line). In this manner, in the third embodiment, the light shielding member 3C(2) is arranged so that the light shielding member 3C(2) has a complementary shape on the opposite sides of the template TC.

FIG. 8 is an explanatory diagram of an arrangement of the imprint shots. FIG. 8 illustrates a top view of four imprint shots. An imprint process is performed in order of, for example, a first shot S1, a second shot S2, a third shot S3, and a fourth shot S4.

The imprint process is performed so that, for example, the kerf region 32C(1) of the first shot S1 and the kerf region 32C(1) of the second shot S2 are fitted to each other. Specially, the imprint process is performed so that the kerf region 32C(1) arranged at the left end of the first shot S1 and the light shielding member 3C(2) arranged at the right end of the second shot S2 are superposed on each other. At this time, the imprint process is performed so that the light shielding member 3C(2) arranged at the left end of the first shot S1 and the kerf region 32C(1) arranged at the right end of the second shot S2 are superposed on each other.

Similarly, the imprint process is performed so that the kerf region 32C(1) of the first shot S1 and the kerf region 32C(1) of the third shot S3 are fitted to each other. Further, the imprint process is performed so that the kerf regions 32C(1) of the second and third shots S2 and S3 and the kerf region 32C(1) of the fourth shot S4 are fitted to each other.

A region S1 shown in FIG. 8 is a region where the kerf regions 32C(1) are arranged and superposition with the adjacent shots has not been performed. In the region S1, the resist 40 is not yet in a semi-cured state.

A region S2 shown in FIG. 8 is a region where the kerf regions 32C(1) are arranged and superposition with the adjacent shots is performed. In the region S2, the resist 40 is in a completely cured state. A region S3 shown in FIG. 8 is a region where the kerf regions 320(2) are and the resist 40 is in a completely cured state.

In this manner, in the third embodiment, when it is assumed that the kerf region 32C(1) (a pattern arranged region) is the convex region with respect to the body pattern region 31, and the light shielding member 3C(2) (a dimming region) is the concave region with respect to the body pattern region 31, the template TC is formed so that the opposing sides of the kerf region 32 have a complementary shape between the convex region and the concave region.

In this manner, in the third embodiment, because the kerf region 32C(1) and the light shielding member have a jigsaw shape, overstriking is performed so that the template pattern does not interfere with each other in the adjacent shots at the time of transferring the template pattern to the adjacent shots.

In the template TC, a dimming member having the same light shielding rate as that of the dimming member 3B(1) can be arranged instead of the light shielding member 3C(2). In this case, a pattern can be arranged under the dimming member. A dimming member having the same light shielding rate as that of the dimming member 3B(1) can be arranged instead of the light shielding member 3C(1).

Furthermore, the dimming member 3B(2) can be arranged on the kerf region 32C(2). In this case, pattern can be arranged under the dimming member 3B(2). Further, a complete light-shielding member can be arranged at three points of the kerf region 32C(2). In this case, a pattern can be arranged at the remaining one point of the kerf region 32C(2).

In this manner, in the third embodiment, the light shielding member 3C(2) and the kerf region 32C(1) are arranged in a jigsaw shape so that the kerf regions 32C(1) can be superposed on each other between the adjacent shots.

Accordingly, even when a mark or the like is arranged between the adjacent shots, the adjacent shots can be superposed and imprinted without damaging the template. Further, misalignment between the adjacent shots can be corrected, and the template pattern can be imprinted to the resist 40 efficiently.

### Fourth Embodiment

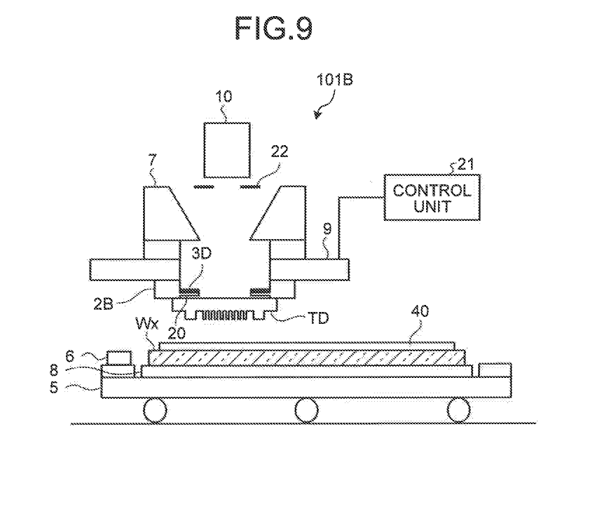

A fourth embodiment is explained next with reference to FIG. 9. In the fourth embodiment, the dimming member 3X is arranged in the imprint apparatus 101X. A case where a dimming member 3D as an example of the dimming member 3X is arranged in an imprint apparatus 101B as an example of the imprint apparatus 101X is explained.

FIG. 9 illustrates a configuration of an imprint apparatus according to the fourth embodiment. The imprint apparatus 101B includes an original plate stage 2B, the substrate chuck 8, the sample stage 5, the reference mark 6, the alignment sensor 7, the stage base 9, the UV light source 10, the control unit 21, and the shutter 22.

The dimming member 3D according to the fourth embodiment is arranged on the original plate stage 2B. The dimming member 3D is arranged on the original plate stage 2B so as to be at substantially the same arrangement position as the dimming member 3A as viewed from the template TX. In other words, the dimming member 3D is arranged so that the arrangement position of the dimming member 3D as viewed from a template TD in a state with the template TD arranged on the original plate stage 2B and the arrangement position of the dimming member 3A as viewed from the template TA in a state with the template TA arranged on the original plate stage 2X become the same arrangement position. In this case, a template pattern is arranged with respect to the template TD in the same region as in the template TA.

The imprint apparatus 101B fixes the template TD so that the dimming member 3D is arranged on the kerf region 32A and the outer peripheral region 33 of the template TD and performs imprint to the resist 40.

The dimming member 3D can be arranged on the original plate stage 2B, for example, so as to be at substantially the same arrangement position as the dimming members 3B(1) and 3B(2) as viewed from the template TX. In other words, the dimming member 3D can be arranged so that the arrangement position of the dimming member 3D as viewed from the template TD in a state with the template TD arranged on the original plate stage 2B and the arrangement position of the dimming members 3B(1) and 3B(2) as viewed. from the template TB in a state with the template TB arranged on the original plate stage 2X become the same. In this case, the template pattern is arranged in the same region of the template TD as in the template TB.

Furthermore, the dimming member 3D can be arranged on the original plate stage 2B so as to be at substantially the same arrangement position as the dimming members 30(1) and 30(2) as viewed from the template TX. In other words, the dimming member 3D can be arranged so that the arrangement position of the dimming member 3D as viewed from the template TD in a state with the template TD arranged on the original plate stage 2B and the arrangement position of the dimming members 3C(1) and 3C(2) as viewed from the template TC in a state with the template TC arranged on the or plate stage 2X become the same. In this case, the template pattern is arranged in the same region of the template TD as in the template TC. Further, the configuration of the imprint apparatus 101B can be such that the position and the arrangement (the shape) of the dimming member 3D are movable. The dimming member 3D can be configured by a plurality of members.

In this manner, in the fourth embodiment, the dimming member 3D is arranged in the imprint apparatus 101B so that UV light similar to UV light irradiated to the resist 40 when any one of the templates TA to TC is used is irradiated. The imprint apparatus 101B performed the imprint process to the resist 40 by the same process as that explained in the first to third embodiments.

In this manner, in the fourth embodiment, the dimming member 3D is arranged in the imprint apparatus 101B so as to be at substantially the same arrangement position as the dimming member 3A. Accordingly, even when a mark or the like is arranged between the adjacent shots, adjacent shots can be superposed and imprinted without damaging the template. Further, misalignment between the adjacent shots can be corrected, and the template pattern can be imprinted to the resist 40 efficiently.

When a semiconductor device (a semiconductor integrated circuit) is manufactured, the imprint process by the imprint apparatus 101X is repeated, for example, for each layer of a wafer process. Specifically, after a layer to be processed is formed on the wafer Wx, the resist 40 is applied onto the layer to be processed. The imprint apparatus 101X then forms a resist pattern on the wafer Wx by transferring a template pattern to the resist 40. An etching device then etches the layer to be processed by using the resist pattern as a mask. Accordingly, an actual pattern corresponding to the resist pattern is formed on the wafer Wx. At the time of manufacturing the semiconductor device, the film-forming process of the layer to be processed, the imprint process, the etching process, and the like described above are repeated for each layer.

According to the first to fourth embodiments, the imprint process can be performed after correcting misalignment between adjacent shots, without damaging the template TX.

While certain embodiments have been described, these embodiments have been presented by way of example only and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit or the inventions.

What is claimed is:

1. An imprint method comprising:
contacting a template having a first pattern arranged in a central region and a second pattern arranged in a first outside region which is an outside region of the central region, against a first imprint shot in a resist on a substrate;
irradiating light for curing the resist to the resist in a partial region of a first resist region contacted by the first outside region, via a dimming member that dims an amount of the light so that the resist has hardness lower than target hardness, at a time of irradiating the light to the first imprint not via the template;
separating the template from the first imprint shot;
contacting the template against a second imprint shot so that the second imprint shot adjacent to the first imprint shot and the first imprint shot are superposed in a superposed region including the partial region;
irradiating the light so that the resist in the partial region reaches the target hardness at a time of irradiating the light to the second imprint shot via the template; and
separating the template from the second imprint shot.

2. The imprint method according to claim 1, wherein
the dimming member is arranged above the first outside region, and
the partial region and the superposed region are a same region.

3. The imprint method according to claim 1, wherein
the first outside region has an arrangement region where the second pattern is arranged, and a dimming region different from the arrangement region on which the dimming member is arranged on an upper side,
when it is assumed that the arrangement region is a convex region with respect to the central region and the dimming region is a concave region with respect to the central region when the template is viewed from an upper surface thereof, opposing sides of the first outside region have a complementary shape between the convex region and the concave region, and
the template is contacted against the second imprint shot so that the convex region and the concave region are fitted to each other between adjacent shots and the superposed region becomes a rectangular region.

4. The imprint method according to claim 3, wherein
the resist contacted by the dimming region is cured halfway by irradiating the light to the resist via the dimming member, and the resist contacted by the arrangement region is cured to the target hardness, and
the resist contacted by the arrangement region and cured at the time of irradiating the light to the first imprint shot and the resist contacted by the arrangement region and cured at the time of irradiating the light to the second imprint shot are formed in the superposed region.

5. The imprint method according to claim 1, wherein
the first outside region is a rectangular annular region, and
a member that promotes a degree of cure of the resist by one fourth by dimming an amount of the light is arranged above an apex region of the first outside region where adjacent four imprint shots are superposed.

6. The imprint method according to claim 1, wherein the dimming member is formed on the template.

7. The imprint method according to claim 1, wherein the dimming member is arranged in an imprint apparatus that performs an imprint process to the substrate.

8. The imprint method according to claim 1, wherein
the template includes a second outside region which is an outside region of the first outside region, in which a pattern is not arranged, and
the dimming member is arranged at a position covering a whole surface of the first outside region and a position covering a part of the second outside region.

9. The imprint method according to claim 1, wherein the resist is applied to a whole surface of the substrate or to substantially a whole surface of the substrate.

10. A template comprising:
a first pattern arranged in a central region;
a second pattern arranged in a first outside region which is an outside region of the central region; and
a dimming member arranged on an upper layer side of the first outside region to dim an amount of light that cures a resist on a substrate.

11. The template according to claim 10, wherein the dimming member promotes a degree of cure of the resist by half by dimming an amount of the light.

12. The template according to claim 10, wherein
the first outside region has an arrangement region where the second pattern is arranged, and a dimming region different from the arrangement region on which the dimming member is arranged on an upper side, and
when it is assumed that the arrangement region is a convex region with respect to the central region and the dimming region is a concave region with respect to the central region when the template is viewed from an upper surface thereof, opposing sides of the first outside region have a complementary shape between the convex region and the concave region.

13. The template according to claim 12, wherein the dimming member has a dimming degree such that when the light is irradiated to the resist via the dimming member, the resist contacted by the dimming region is cured halfway.

14. The template according to claim 10, wherein
the first outside region is a rectangular annular region, and
a member that promotes a degree of cure of the resist by one fourth by dimming an amount of the light is arranged above an apex region at the first outside region where adjacent four imprint shots are superposed.

15. The template according to claim 10, wherein the template has stiffness in a first region contacted against the superposed region, which is stronger than that in a second region contacted against a region other than the superposed region of the template region.

16. The template according to claim 10, further comprising a second outside region that is an outside region of the first outside region in which a pattern is not arranged, wherein
the dimming member is arranged at a position covering a whole surface of the first outside region and a position covering a part of the second outside region.

17. The template according to claim 10, wherein the dimming member is configured by using chromium or quartz having a low purity.

18. An imprint apparatus comprising:
a stage base that contacts a template having a first pattern arranged in a central region and a second pattern arranged in a first outside region which is an outside region of the central region, against a resist on a substrate;
a light source that irradiates light for curing the resist to the first imprint shot via the template;
an irradiation unit that allows or blocks passage of light irradiated from the light source to the template side;
a control unit that controls the stage base and the irradiation unit; and
a dimming member that dims an amount of the light by covering the first outside region in a state where the template is contacted against the resist, so that the contacted resist has hardness lower than target hardness, wherein
the control unit controls the stage base and the irradiation unit to
contact the template against a first imprint shot in the resist,
irradiate the light to the resist in a partial region of the first resist region contacted by the first outside region via the dimming member, at a time of irradiating the light to the first imprint shot via the template,
separate the template from the first imprint shot,
contact the template against a second imprint shot so that the second imprint shot adjacent to the first imprint shot and the first imprint shot are superposed in a superposed region including the partial region,
irradiate the light so that the resist in the partial region reaches a target hardness at a time of irradiating the light to the second imprint shot via the template, and
separate the template from the second imprint shot.

19. The imprint apparatus according to claim 18, wherein
the stage base has an original-plate support unit that supports the template, and
the dimming member is arranged in the original-plate support unit.

20. The imprint apparatus according to claim 18, further comprising an application unit that applies the resist to a whole surface of the substrate, wherein
the control unit controls an imprint process by using the substrate applied with the resist on the whole surface.
